(19) United States
(12) Patent Application Publication
(10) Pub. No.: US 2013/0099298 A1
(43) Pub. Date: Apr. 25, 2013

(54) SEMICONDUCTOR DEVICE AND METHOD FOR MANUFACTURING THE SAME

(71) Applicant: Se Hyun KIM, Icheon-si (KR)

(72) Inventor: Se Hyun KIM, Icheon-si (KR)

(73) Assignee: Hynix Semiconductor Inc., Icheon (KR)

(21) Appl. No.: 13/350,519

(22) Filed: Jan. 13, 2012

(30) Foreign Application Priority Data
Oct. 24, 2011 (KR) 10-2011-0108823

(51) Int. Cl. H01L 27/108; H01L 21/28; H01L 29/78

(52) U.S. Cl. 257/296; 257/330; 438/589; 257/E27.084; 257/E29.262; 257/E21.19

(57) ABSTRACT

A semiconductor device comprises a buried gate formed in a mat and in an adjacent dummy region. A space larger than is conventional is formed in a dummy region of a mat edge where the buried gate is to be created. This larger space inhibits shortening of an end of a buried gate and reduction in pattern size attributable to lithographic distortion arising between patterned (mat) and unpatterned (dummy) regions. Device reliability is thereby improved by avoiding gap-fill defects of a gate material.

### CROSS-REFERENCE TO RELATED APPLICATION

The present application claims priority to Korean patent application No. 10-2011-0108823 filed on Oct. 24, 2011, which is incorporated by reference in its entirety.

### BACKGROUND OF THE INVENTION

1. Technical Field

The inventive concept relates generally to a semiconductor device and a method for manufacturing the same, and more particularly to a semiconductor device comprising a buried gate disposed in a dummy region of an edge of a cell region and a method for manufacturing the same.

2. Related Art

Semiconductor devices include a plurality of unit cells including a capacitor and a transistor. The capacitor is used to store data and the transistor is used to transfer data between the capacitor and a bit line in response to a control signal (a word line) using a semiconductor property in which electric conductivity is changed according to conditions. The transistor has three parts: a gate, a source, and a drain. Charges move between the source and drain according to the control signal input to the gate. The charges move between the source and drain through a channel region using semiconductor properties.

When a conventional transistor is fabricated on a semiconductor substrate, the gate is formed over the semiconductor substrate and then the source and drain are formed by implanting impurities into the semiconductor substrate, thereby forming the channel region between the source and drain below the gate. With the increasing degree of data storage capacity and integration for semiconductor memory devices, there is demand for fabricating unit cells in more scaled down sizes. That is, the design rule of the capacitor and transistor included in the unit cell and thus a channel length of a cell transistor is reduced. Thereby, short channel effect and drain induced barrier lowering (DIBL) in a conventional transistor are caused, and thus reliability is degraded. Phenomena caused due to reduction of the channel length can be overcome when a threshold voltage is maintained so that the cell transistor performs normal operations. Conventionally, as the channel length is shorter, a doping concentration of an impurity in a region in which the channel region is formed in increased.

However, with reduction of the design rule to below 100 nm, increase of the doping concentration in the channel region causes an electric field in a storage node junction to increase, thereby resulting in degradation of refresh characteristic in semiconductor memory devices. To overcome this, a cell transistor having a three-dimensional (3D) channel structure in which a long channel is ensured to maintain a channel length even when the design rule is reduced has been used. That is, although channel width in a horizontal direction is short, the doping concentration can be reduced by the ensured channel length in the horizontal direction and degradation of the refresh characteristic can be prevented.

In addition, as the degree of integration of semiconductor devices is increased, a distance between a gate coupled to a cell transistor and a bit line is reduced. Thereby, parasitic capacitance is increased and an operation margin of a sense amplifier amplifying data transferred through the bit line is degraded, which has a negative effect on the reliability of a semiconductor device.

To solve this, it has been suggested to form a buried gate structure in which a gate is formed within a trench instead of a surface of a semiconductor substrate, in order to reduce the parasitic capacitance between a gate and a bit line. The buried type gate structure is formed by forming a conductive material within a recess formed in a semiconductor substrate, and forming an insulating layer on the conductive material so that the gate is buried within the semiconductor substrate. Therefore, electrical isolation from a bit line or a bit line contact plug formed over the semiconductor substrate in which a source/drain is formed can be more ensured.

However, in the process for forming this buried type gate, a distortion phenomenon of patterns appears by diffraction and interference of light from a dummy region of a mat edge, to a main cell region of the mat middle portion. Specifically, the pattern end becomes shorter or the pattern size is reduced by an optical proximity effect resulting from a photo process, which results in distortion of patterns. Moreover, such defect increases toward patterns of the dummy region. Referring to FIGS. 1a and 1b, a gap-fill process defect of a gate material formed in the cell region and the dummy region will be described as follows.

FIGS. 1A and 1B show a plurality of buried gates formed in the cell region and the dummy region. As shown in A′, toward the dummy region from the cell region, a pattern disposed in the end of a buried gate 35 is not completely formed or a gate metal layer is not completely filled in the end of the buried gate 35.

FIGS. 2A to 2C are cross-sectional views taken along A-A′ and B-B′ lines of FIG. 1B

Referring to FIGS. 2A to 2E, the process by which the above-described problem is generated will be described as follows. Referring to FIG. 2A, a pad nitride film pattern 13 is formed over a semiconductor substrate 10 and the semiconductor substrate 10 is etched with the pad nitride film pattern 13 as an etch mask to form a trench for device isolation. In the trench for device isolation, an insulation material is buried to form a device isolation film 15.

Referring to FIG. 2B, a hard mask pattern 20 that defines buried gate is formed, and the pad nitride film pattern 13 and the semiconductor substrate are etched with the hard mask pattern 20 as an etch mask to form a trench 30. In the dummy region disposed in the edge of the cell region, as shown in A′ of FIG. 1A, a pattern may not be completely formed or its size may be reduced.

If the pattern is not completely formed, a subsequent process (see FIG. 2C) for burying a gate material 35 in the trench 30 may result in a gap-fill defect phenomenon that the gate material 35 is not completely buried due to a lack of process margin of the trench as shown in A′.

In a subsequent process for forming a metal contact (40 of FIG. 1B) to apply a gate voltage, a failure (e.g. short) may be generated between the metal contact and the substrate because the material for stopping the etching is not completely formed. Although the etching is properly stopped, a desired voltage may not be normally applied to a selected gate due to inadequate gap-fill of the device of the end of the buried gate 35. As a result, the operating characteristic of DRAM may be degraded.

### BRIEF SUMMARY OF THE INVENTION

Various embodiments of the invention are directed to forming a space where a buried gate is to be formed in a dummy region of a mat edge larger than in the conventional art, thereby preventing phenomena that the end of the buried gate becomes shorter or the pattern size is reduced and removing the gap-fill defect of the gate material to improve the operating characteristic of the device.

According to one aspect of an exemplary embodiment, a semiconductor device comprises: a buried gate formed at both sidewalls of a trench disposed in a semiconductor substrate; and an insulating film for burying a space between the buried gates and penetrating the middle portion of the trench.

The buried gate is formed in a dummy region of an edge of a cell region.

The buried gate includes tungsten.

The semiconductor device further comprises a sealing nitride film over the buried gate in the trench.

According to another aspect of an exemplary embodiment, a semiconductor device comprises: a first trench disposed in a cell region of a semiconductor substrate; a second trench disposed in a dummy region of the semiconductor substrate and having a larger line-width than that of the first trench; a first buried gate formed in the first trench; a second buried gate formed in both sidewalls of the second trench; and an insulating film for burying a space between the second buried gate and penetrating the middle portion of the second trench.

The line-width of the second trench is formed with a line-width including the first trench and another first trench adjacent to the first trench.

The first buried gate is formed in the lower portion of the first trench.

The second buried gate is formed in the lower portion of both sidewalls of the second trench.

The insulating film is penetrated to the top side of the semiconductor substrate disposed in the lower portion of the second trench.

The semiconductor device further comprises a sealing nitride film in the upper portion of the first buried gate and the second buried gate.

According to another aspect of an exemplary embodiment, a method for manufacturing a semiconductor device comprises: forming a trench in a semiconductor substrate; forming a buried gate at both sidewalls of the trench; and burying a space between the buried gates to penetrate the middle portion of the trench.

The trench is formed in a dummy region of an edge of a cell region.

The forming-a-buried-gate-at-both-sidewalls-of-the-trench further includes: forming a gate material in the lower portion of the trench; forming a sealing nitride film over the gate material; and etching the sealing nitride film and the gate material to form a hole that exposes the semiconductor substrate disposed in the lower portion of the trench.

The forming-an-insulating-film further includes forming a nitride film that buries the hole.

According to another aspect of an exemplary embodiment, a method for manufacturing a semiconductor device comprises: forming a first trench and a second trench having a larger line-width than that of the first trench in a cell region and a dummy region of a semiconductor substrate, respectively; forming a gate material in the first trench and the second trench; etching the gate material disposed in the middle portion of the second trench to form a hole; and burying an insulating film in the hole to form a buried gate at both sidewalls of the second trench.

The line-width of the second trench is formed with a line-width including the first trench and another first trench adjacent to the first trench.

The forming-a-gate-material includes: forming a conductive material over the top portion including the first trench and the second trench; and etching the conductive material by an etch-back process so that the conductive material remains only in the lower portion of the first trench and the second trench.

The method further comprises forming a sealing nitride film over the top portion of the first trench and the second trench including the gate material after forming the gate material.

The forming-a-hole further includes etching the sealing nitride film and the gate material disposed in the middle portion of the second trench to expose the semiconductor substrate disposed in the lower portion of the second trench.

The gate material is separated into two in the forming-a-hole.

According to another aspect of an exemplary embodiment, a memory cell comprising: a transistor including a buried gate formed at both sidewalls of a trench disposed in a semiconductor substrate, an insulating film obtained by burying a space between the buried gates to penetrate the middle portion of the trench and a gate junction region; and a storage unit connected to the gate junction region.

The buried gate is formed in a dummy region of an edge of a cell region.

The storage unit is a capacitor.

According to another aspect of an exemplary embodiment, a memory cell array comprises at least one or more memory cells each including: a transistor including a buried gate formed at both sidewalls of a trench disposed in a semiconductor substrate, an insulating film obtained by burying a space between the buried gates to penetrate the middle portion of the trench and a gate junction region; and a storage unit connected to the gate junction region.

The buried gate is formed in a dummy region of an edge of a cell region.

According to another aspect of an exemplary embodiment, a memory device comprises: a core circuit region; and a memory cell array including: a transistor including a buried gate formed at both sidewalls of a trench disposed in a semiconductor substrate, an insulating film obtained by burying a space between the buried gates to penetrate the middle portion of the trench and a gate junction region; and a storage unit connected to the gate junction region.

The core circuit region further includes: a row decoder for selecting one from word lines of the memory of the memory cell array; a column decoder for selecting one from bit lines of the memory cell array; and a sense amplifier for sensing data stored in the memory cell selected by the row decoder and the column decoder.

According to another aspect of an exemplary embodiment, a memory module comprises a memory device that comprises: a transistor including a buried gate formed at both sidewalls of a trench disposed in a semiconductor substrate, an insulating film obtained by burying a space between the buried gates to penetrate the middle portion of the trench and a gate junction region; a memory cell array including a storage unit connected to the gate junction region; a row decoder; a column decoder; and a sense amplifier, and an external input/output line.

The memory device further includes a data input buffer, a command/address input buffer and a resistor.

The external input/output line is electrically connected to the memory device.

According to another aspect of an exemplary embodiment, a memory system comprises a plurality of memory modules, each memory module that includes: a memory cell array including a transistor including a buried gate formed at both sidewalls of a trench disposed in a semiconductor substrate, an insulating film obtained by burying a space between the buried gates to penetrate the middle portion of the trench and a gate junction region, and a storage unit connected to the gate junction region; a memory device including a row decoder, a column decoder and a sense amplifier; and a command link and a data link, a memory controller for communicating data and command/address with the memory module.

These and other features, aspects, and embodiments are described below.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1A and 1B are plane diagrams illustrating a conventional prior art;

FIGS. 2A to 2C are cross-sectional views taken along A-A′ and B-B′ lines of FIG. 1B;

FIGS. 3A and 3B are plane diagrams illustrating a semiconductor device according to an exemplary embodiment of the present invention;

FIGS. 4A to 4E are cross-sectional views taken along C-C′ and D-D′ lines of FIG. 3B;

FIG. 5 is a circuit diagram illustrating a memory cell array according to an exemplary embodiment of the present invention;

FIG. 6 is a block diagram illustrating a memory device according to an exemplary embodiment of the present invention;

FIG. 7 is a block diagram illustrating a memory module according to an exemplary embodiment of the present invention; and

FIG. 8 is a block diagram illustrating a memory system according to an exemplary embodiment of the present invention.

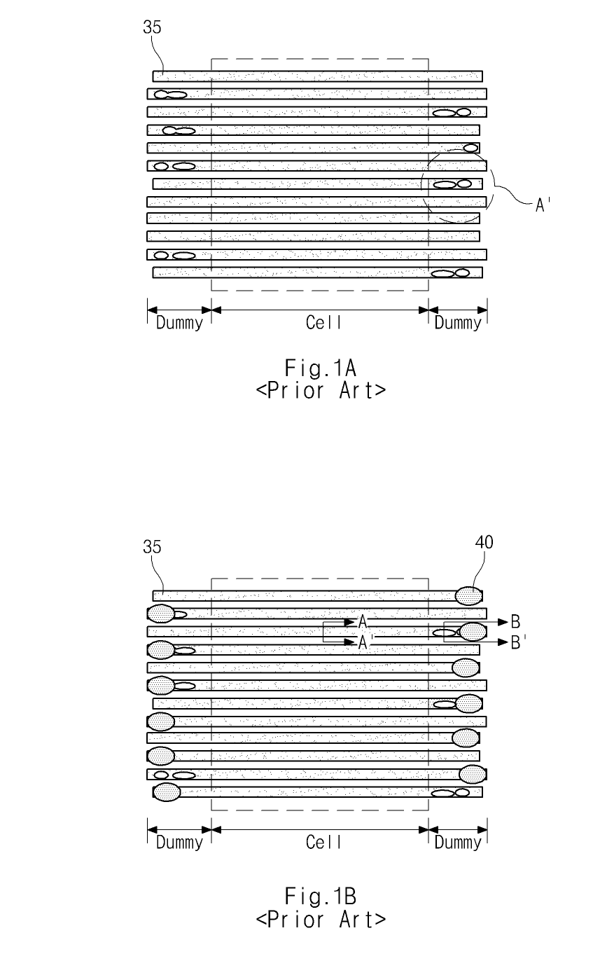

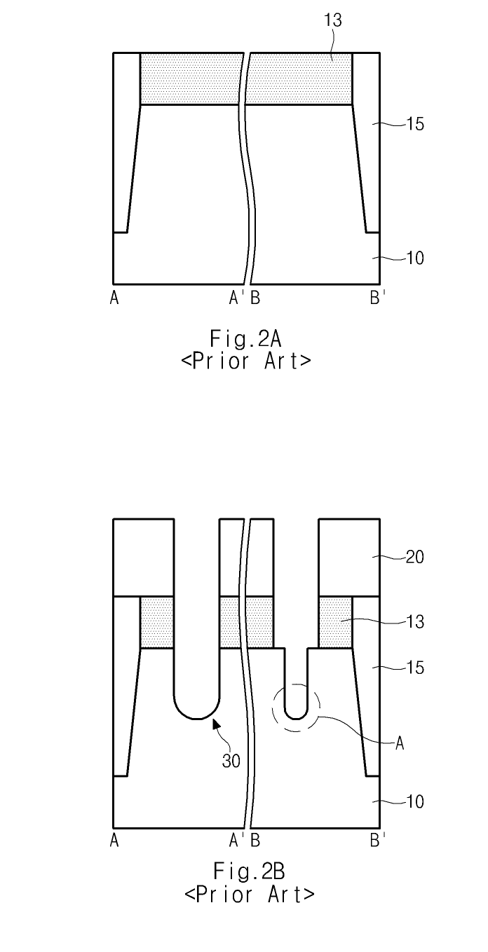

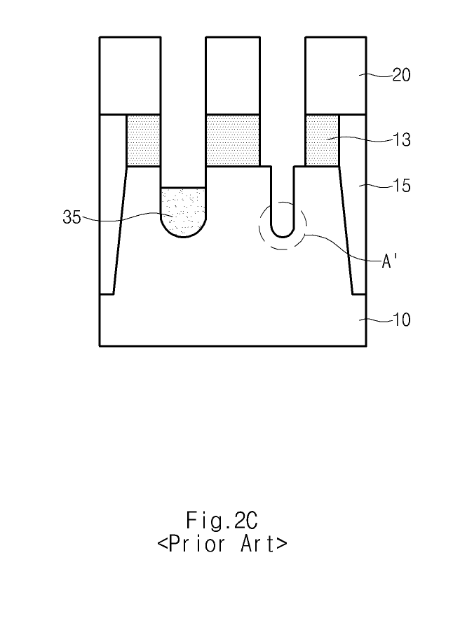

### DESCRIPTION OF EMBODIMENTS

Exemplary embodiments of the present invention will be described in detail with reference to the attached drawings.

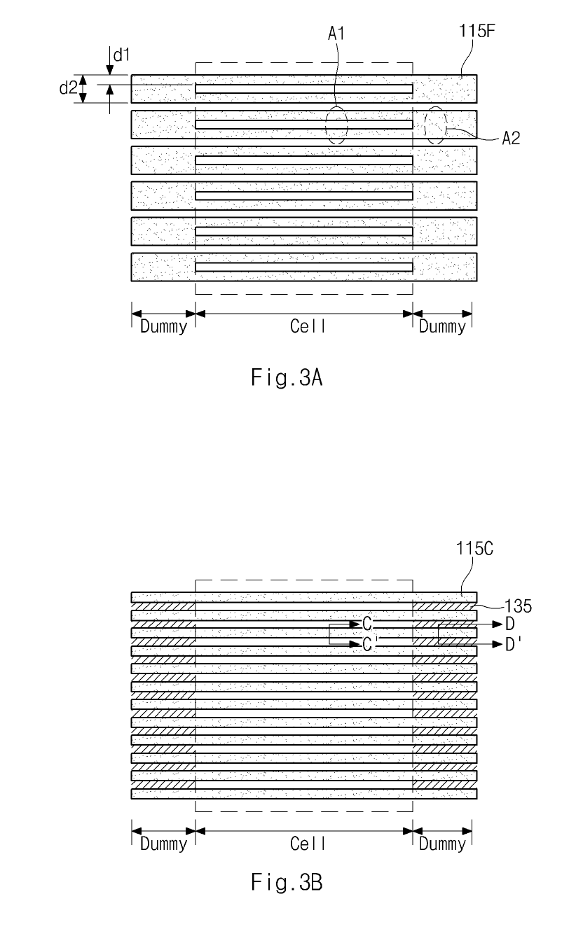

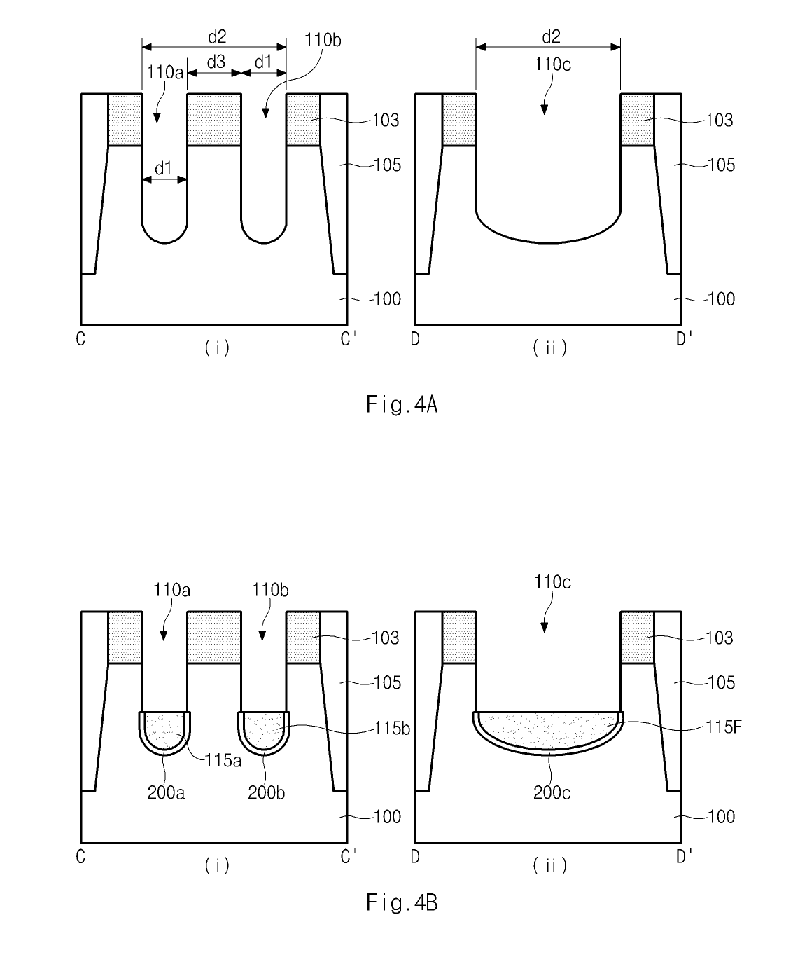

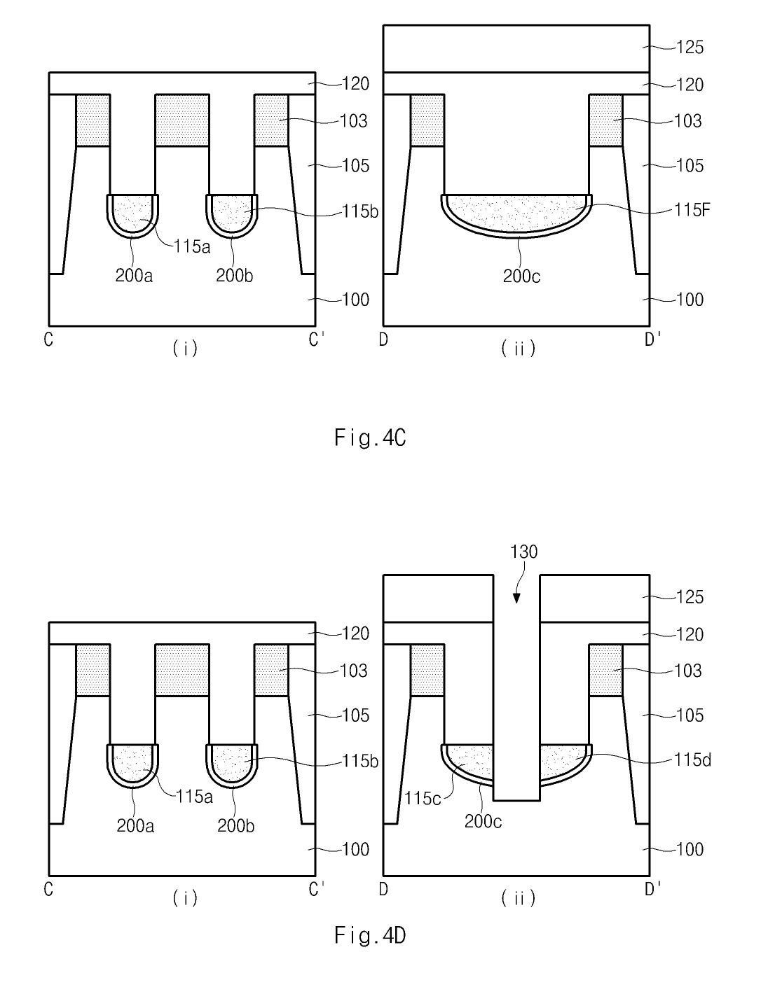

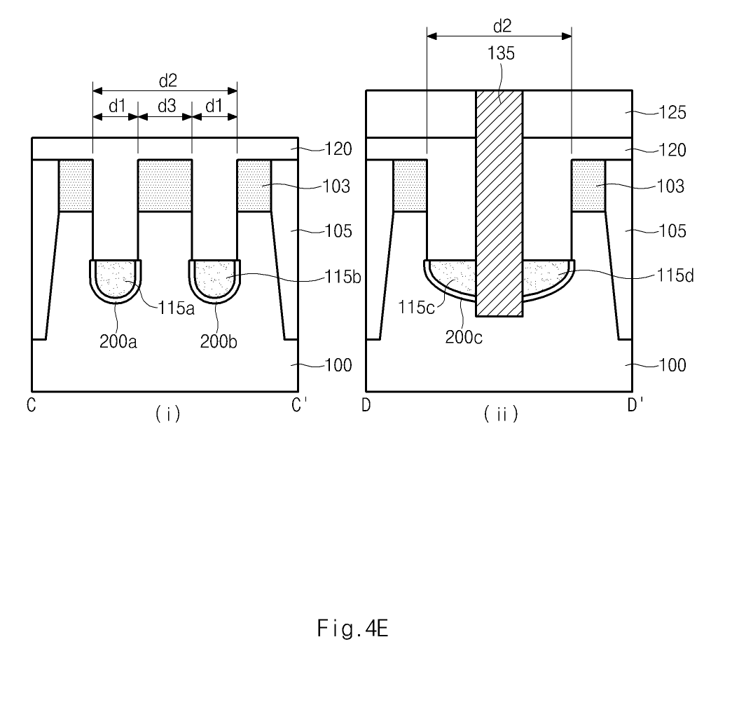

Referring to FIGS. 3A-3B and 4E, an embodiment according to the present invention includes a first active region (A1) formed in a cell region of a substrate (100) and a second active region (A2) formed in a dummy region of the substrate. The dummy region extends from the cell region. In FIG. 4E, (i) denotes a cell region and (ii) denotes a dummy region.

First and second buried cell gate (115a, 115b) are arranged in parallel to each other and pass across the first active region (A1). First and second buried dummy gate (115c, 115d) are arranged in parallel to each other and pass across the first active region (A2).

A conductive pattern is formed between the first and second buried cell gates (115a, 115b). An insulating film (135) is formed between the first and second buried dummy gates (115c, 115d). The first and the second buried cell gates (115a, 115b) in the cell region are coupled to the conductive pattern (100), respectively. On the other hand, in the dummy region the insulating film (135) is formed between the first and the second buried dummy gates (115c, 115d) to insulate the first and the second buried dummy gates (115c, 115d) from the substrate.

A pad nitride pattern (103) may be formed over the first and second buried cell gates (115a, 115b), and over the first and second buried dummy gates (115c, 115d). The conductive pattern may be formed of the substrate (100) or any other semiconductor material.

The insulating film (135) may extend from the conductive pattern. The widths of the first and the second buried cell gates (115c, 115d) may be as same as each other. The widths of the first and the second buried dummy gates (115c, 115d) may be substantially as same as the first and the second buried cell gates (115a, 115b), respectively. The width of the insulating film (135) may be substantially as same as the width of the conductive pattern.

First and second gate insulating films (200a, 200b) are formed between the conductive pattern and each of the first and the second buried cell gates (115a, 115b) in the cell region, respectively, to form first and second channel along the contours of the first and the second buried cell gates (115a, 115b). Third and fourth gate insulating films (200c, 200d) may or may not be formed between the insulating film (135) and each of the first and the second buried dummy gates in the dummy region, respectively.

15[0052] When the first and the second gate insulating films (200a, 200b) are formed, but the third and the fourth gate insulating films (200c, 200d) are not be formed, the width of the insulating film (135) may be slightly narrower than that of the conductive pattern. However, the thickness of the first and the second gate insulating films (200a, 200b) are relatively thin, the width of the insulating film (135) may be treated as substantially same as that of the conductive pattern.

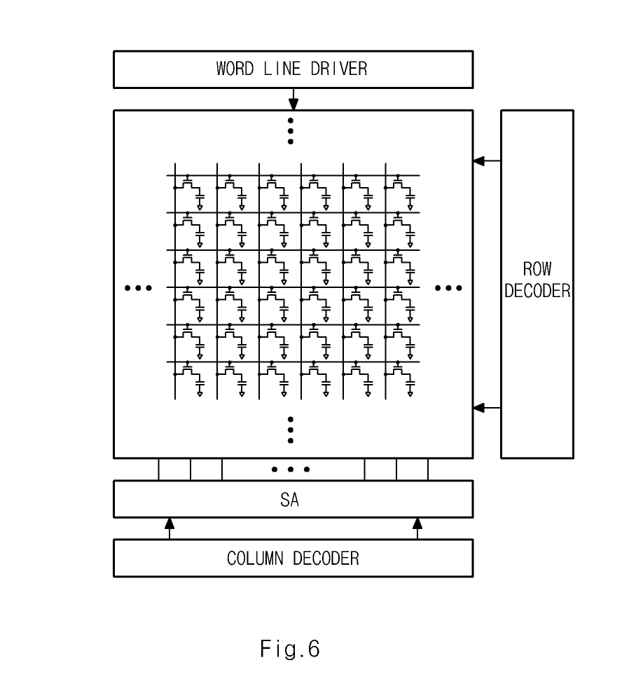

A word line driver (See FIG. 6) is formed to be coupled to any of the first and the second buried dummy gates each formed in the dummy region. The word line driver is coupled to any of the first and the second buried dummy gates through first and second word line driver contacts each formed in the dummy region, respectively.

The dummy region includes first and second dummy regions. As shown in FIG. 3B, the first dummy region may extend from the cell region in a first direction (e.g., in to the left direction in FIG. 3B) to be located at the left side of the cell region. On the other hand, the second dummy region may extend from the cell region toward a second direction opposite to the first direction (e.g., into the right direction in FIG. 3B) to be located at the right side of the cell region. The first and the second word line driver contacts may be alternatively located in the first and the second dummy regions.

More specifically, FIGS. 3A and 3B are plane diagrams illustrating a cell region and a dummy region according to an exemplary embodiment of the present invention. A plurality of buried gates formed in the cell region and the dummy region are briefly shown in FIGS. 3A and 3B.

Referring to FIGS. 3A and 4A, first and second trenches (110a, 110b in FIG. 4A) and a third trench (110c in FIG. 4A) are formed in a cell region and a dummy region, respectively. A line-width (d2) of the third trench (110c in FIGS. 4A-B) may be the sum of the width (d1) of the first buried cell gate (115a), a width (d1) of the second buried cell gate (115b), a width of the substrate (100) between the first buried cell gate (115a) and the second buried cell gate (115b). Referring to FIG. 3B, the insulating film 135 is formed in the middle of the first and the second buried dummy gates (115c, 115d) in the dummy region.

As described above, since the third trench in the dummy region is formed in a size larger (for example, three times larger) than a conventional trench, pattern distortion of a buried gate in the dummy region can be prevented. As a result, electrical short between a word line driver contact and the substrate due to a gap-fill defect can be prevented. Also, an increase in contact resistance of the buried gate due to failure of the gap-fill process is prevented. FIGS. 4A to 4E are cross-sectional diagrams illustrating a method for manufacturing a semiconductor device according to an exemplary embodiment of the present invention, wherein (i) denotes a cell region and (ii) denotes a dummy region.

An example for forming a semiconductor device according to the present invention is as follows.

Referring to FIGS. 3A-4E, a first active region (A1) is formed in a cell region of a substrate (100). A second active region (A2) is formed in a dummy region of the substrate. The dummy region extends from the cell region.

The substrate in the cell region is etched to form a first trench (110a) passing across the first active region (A1). The first trench has a width d1.

The substrate in the cell region is patterned to form a second trench (115b) spaced apart from the first trench by a width d3. The first and the second trenches may be formed at the same time. The second trench (115b) is substantially parallel to the first trench (115a) and passes across the first active region. The second trench may have a width d2.

The substrate in the dummy region is patterned to form a third trench (110c). The third trench has a width (d2) and extends from the first and the second trenches to pass across the second active region.

The first and second trenches (110a, 110b) are filled with first conductive material to form first and second buried cell gates. The third trench is filled with second conductive material to form a dummy conductive pattern.

A fourth trench 130 is formed in the middle of the dummy conductive pattern to divide the dummy conductive pattern into first and second buried dummy gates (115c, 115d). The fourth trench is filled with insulating material to form an insulating film (135).

The first buried dummy gate (115c) may couple to the first buried cell gate. The second buried dummy gate (115d) may couple to the second buried cell gate. The insulating film (135) may extend from the substrate between the first and the second buried cell gates.

The first and the second trenches may be connected to the third trench. The first conductive material and the second conductive material may be the same. The step of filling the first and second trenches with the first conductive material and the step of filling the third trench with the second conductive material may be performed substantially at the same time.

A width of the insulating film (135) is substantially the same as d3. A width of the first buried dummy gate (115c) is substantially as same as d1, and a width of the second buried dummy gate (115b) is also substantially as same as d1.

More specifically, referring to FIG. 4A, a pad oxide film (not shown) and a pad nitride film are formed over a semiconductor substrate 100 in the cell region and the dummy region, and a photoresist film (not shown) is formed over the pad nitride film. The pad oxide film (not shown) is formed to inhibit the stress of the pad nitride film from being transmitted into the semiconductor substrate. An exposing and developing process is performed on the photoresist film (not shown) to form a photoresist pattern (not shown) that defines first and second active regions (A1, A2) in the cell region and the dummy region, respectively. The pad nitride film, the pad oxide film (not shown) and the semiconductor substrate 100 are sequentially etched with the photoresist pattern (not shown) as an etch mask to form an ISO trench for device isolation patterns (105).

An oxidation process may be performed to form a linear oxide film (not shown) at the inner wall of the ISO trench. The linear oxide film (not shown) is formed to prevent a matrix defect from occurring at the exposed surface of the semiconductor substrate after forming the ISO trench for device isolation.

A liner nitride film (not shown) and a liner oxide film (not shown) are formed over the semiconductor substrate 100 including the oxide film pattern (not shown), the pad nitride pattern 103 and the trench for device isolation. The liner nitride film (not shown) may be formed to prevent oxidation of the inner wall of the trench for device isolation and inhibit stress generation in a subsequent process. Also, the liner oxide film (not shown) may be formed to inhibit a stress from being directly transmitted into the trench for device isolation upon deposition of an insulating material for burying the trench for device isolation or to remove non-uniformity resulting from a deposition speed difference by a material difference between the pad nitride film pattern 103 and the semiconductor substrate 100 exposed by the trench for device isolation.

An insulating material for device isolation is filled in the ISO trench for device isolation to form a device isolation film 105. The insulating material for device isolation includes an oxide film. For example, High Density Plasma (HDP) may be used.

The semiconductor substrate 100 and the pad nitride film pattern 103 in the active region are etched to form a first trench 110a and a second trench 110b in the cell region. Then, the semiconductor substrate 100 and the pad nitride film pattern 103 in the dummy region are etched to form a third trench 110c in the dummy region. The first, the second, and the third trenches 110a, 110b, 110c are trenches for forming buried gates. The first trench 110a or the second trench 110b may be formed to have a line-width (d1). The line-width d1 may be the same as the line width of a conventional buried gate. third trench 110c is formed to have a line-width (d2). In this way, since the third trench 110c is formed in a large size, thereby process tolerance for forming the third trench 110c with a space margin is enhanced.

Referring to FIG. 4B, an oxidation process is performed to form first and second gate insulating film (200a, 200b) over the surface of the semiconductor substrate 100 disposed on the inner wall of the first trench 110a and the second trench 110b. An oxidation process may or may not be performed in the dummy region (A2) to form a third gate insulating film (200c) over the inner wall of the third trench 110c.

A gate material (conductive) is filled in the first trench 110a, the second trench 110b, and the third trench 110c. The line-width of the third trench 110c formed in the dummy region is large enough to prevent a gap-fill defect in the third trench 110c. The gate material may include tungsten. An etch-back process may be performed to so that the gate material 115 remains only in lower parts of the first, the second and the third trenches (110a, 110b, 110c) to form first and second buried cell gates (115a, 115b) and a dummy conductive pattern (115f).

Referring to FIG. 4C, a sealing film 120 is formed over the entire top portion of the semiconductor substrate 100 including the first, the second, and the third trenches (110a, 110b, 110c) where the first and second buried cell gates (115a, 115b) and a dummy conductive pattern (115f) are formed. The sealing film 120 may be formed with a material including a nitride film. The sealing film 120 is formed to fill the first, the second and the third trenches (110a, 110b, 110c).

A hard mask layer 125 is formed over the sealing film 120 A photoresist pattern (not shown) that exposes the middle portion of the third trench 110c is formed over the hard mask layer 125.

Referring to FIG. 4D, the hard mask layer 125 is etched with the photoresist pattern (not shown) as an etch mask to form a hard mask pattern 125a. After the photoresist pattern (not shown) is removed, the sealing film 120 and the gate material 115 are etched with the hard mask pattern 125a as an etch mask to form a fourth trench 130 that exposes the semiconductor substrate 100 below the dummy conductive pattern 115f. The etching process is performed until the semiconductor substrate 100 is exposed, thereby obtaining the fourth trench 130. An over-etching process may be performed to further etch the exposed semiconductor substrate 100. In this way, while the fourth trench 130 is formed, the dummy conductive pattern 115f in the third trench 110c is separated into two to form first and second buried dummy gate 115c and 115d.

Referring to FIG. 4E, after the insulating film 135 is formed, a planarizing process may be performed to expose the hard mask pattern 125a.

As mentioned above, the third trench 110c has a larger size. As a result the electrical short between the word line driver contact and the substrate below the first or the second buried dummy gate (115c or 115d) due to a gap-fill defect of the gate material can be prevented. Also, contact resistance between the first buried cell gate (115a) and the first buried dummy gate (115c), between the second buried cell gate (115b) and the second buried dummy gate (115d), and between any of the first and the second buried dummy gates (115c, 115d) and any of the first and the second word line driver contact can be reduced.

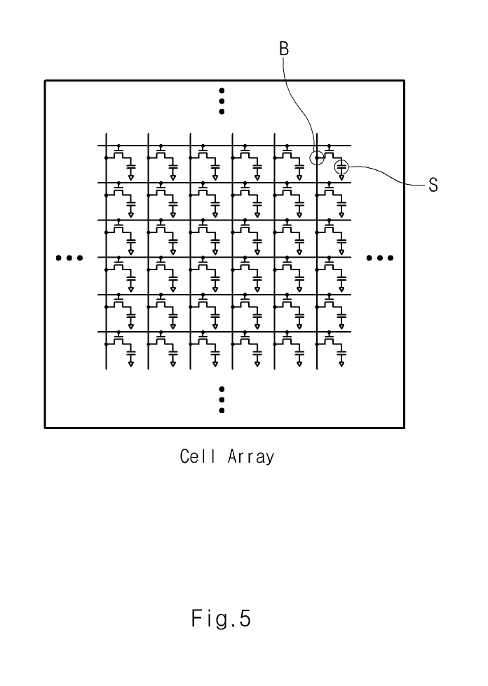

Referring to FIGS. 5-8, an embodiment of the semiconductor device according to the present invention is shown. More specifically, FIG. 5 is a circuit diagram illustrating a memory cell array according to an exemplary embodiment.

A semiconductor device may include a bit line (B) coupled to the conductive pattern (100 in previous figures), and first and second storage units (S) coupled to the bit line (B) through the first and second buried cell gates (115a, 115b in previous figures), respectively.

The device may further includes a row decoder configured to select any of the first and the second buried cell gates (115a, 115b in previous figures), a column decoder configured to select the bit line (B), and a sense amplifier (SA) configured to sense data transmitted from the bit line.

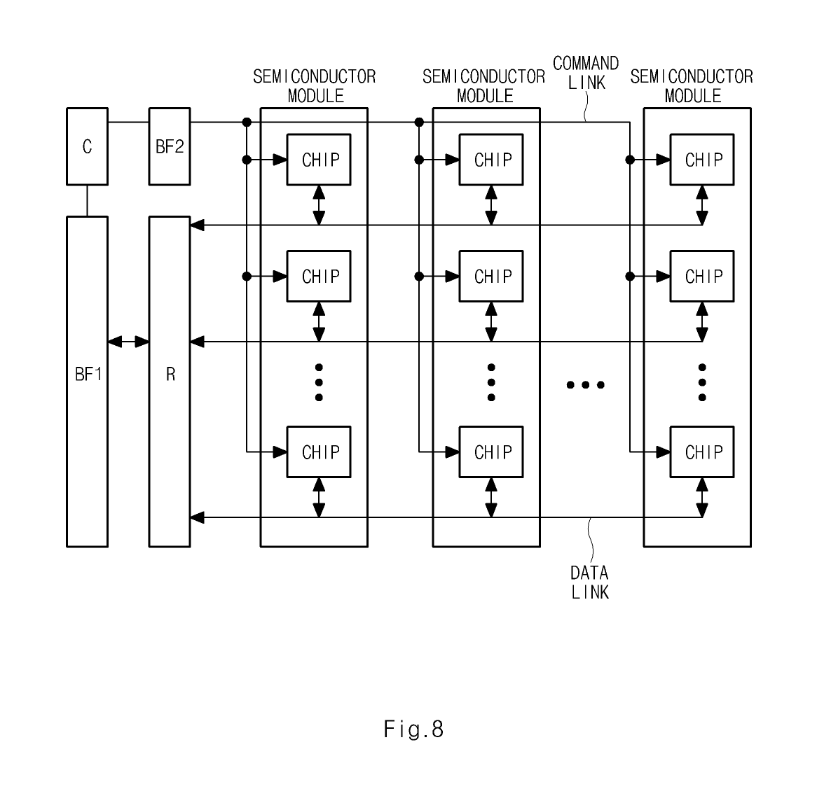

As shown in FIG. 8 the device may further include a data input/output buffer (BF1) coupled to the sense amplifier, a command/address input/output buffer (BF2) coupled to any of the column decoder and the row decoder, and a resistor (R) coupling the data input/output buffer to the sense amplifier (SA). A memory controller (C) may be coupled to any of the row decoder and the column decoder.

Generally, a memory cell array comprises a plurality of memory cells each including one transistor and one capacitor. Such memory cells are located at intersections of bit lines (BL1, . . . , BLn) and word lines (WL1, . . . , WLm). The memory cells are configured to store or output data depending on voltages applied to the bit lines (BL1, . . . , BLn) and the word lines (WL1, . . . , WLm) selected by a column decoder and a row decoder, respectively.

As shown in FIG. 5, in the memory cell array, the bit lines (BL1, . . . , BLn) are formed to extend in a first direction (or “bit line direction”) as a length direction, and the word lines (WL1, . . . WLm) are formed to extend in a second direction (or “word line direction”) as a length direction, so that they are arranged to intersect each other. A first terminal (e.g., drain) of the transistor is coupled to the bit lines (BL1, . . . , BLn), a second terminal (e.g., source) of the transistor is coupled to a capacitor, and a third terminal (e.g., gate) of the transistor is coupled to the word lines (WL1, . . . , WLm). The plurality of memory cells including the bit lines (BL1, . . . , BLn) and the word lines (WL1, . . . , WLm) are located in the semiconductor memory cell array.

FIG. 6 is a block diagram illustrating a memory device according to an exemplary embodiment of the present invention.

As shown in FIG. 6, the memory device may comprise a memory cell array, a row decoder, a column decoder and a sense amplifier (SA). The row decoder is configured to select one corresponding to the memory cell for performing a read or write operation from the word lines of the semiconductor memory cell array so as to output a word line selecting signal RS to the semiconductor memory cell array. The column decoder is configured to select one corresponding to the memory cell for performing a read or write operation from the bit lines of the semiconductor memory cell array so as to output a bit line selecting signal CS to the semiconductor memory cell array. The sense amplifiers are configured to sense data BDS stored in the memory cell selected by the row decoder and the column decoder.

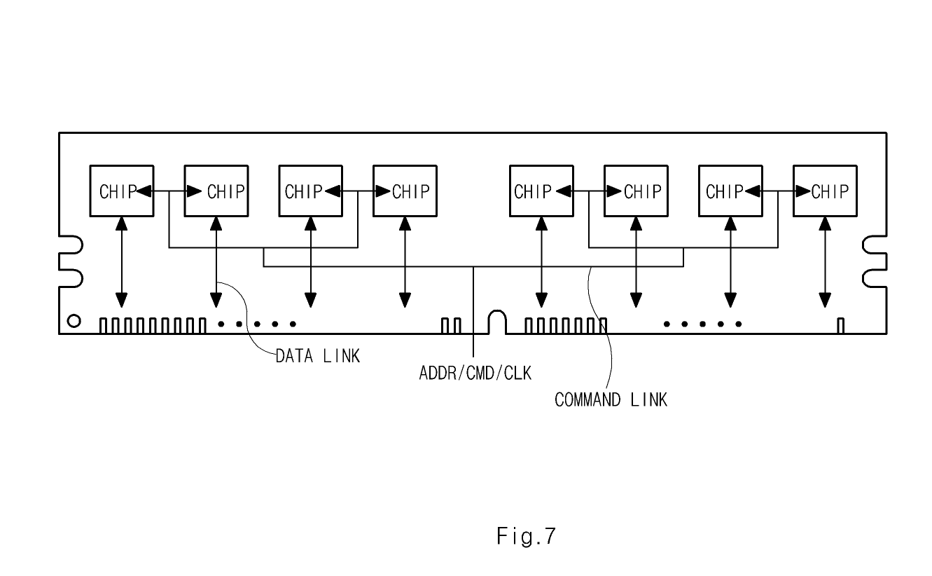

FIG. 7 is a block diagram illustrating a memory module according to an exemplary embodiment of the present invention.

As shown in FIG. 7, the memory module comprises a plurality of semiconductor devices mounted on a module substrate, a command link for enabling the semiconductor device to receive a control signal (address signal (ADDR), a command signal (CMD) and a clock signal (CLK) and a data link for transmitting data connected to the semiconductor device.

The command link and the data link may be the same or similar to those used in a conventional semiconductor module.

Although FIG. 7 shows that eight semiconductor devices are mounted on the front surface of the module substrate, additional semiconductor devices are also mounted on the rear surface of the module substrate in the same manner. That is, the semiconductor device may be mounted on one side or both sides of the module substrate, and the number of the mounted semiconductor devices are not limited to eight on either side. In addition, the material and construction of the module substrate are not specifically limited in a fashion particular to the present invention.

FIG. 8 is a block diagram illustrating a memory system according to an exemplary embodiment of the present invention.

As shown in FIG. 8, the memory system comprises a memory module including one or more semiconductor devices and a controller for communicating data and a command/address signal with the memory module through a system bus.

The memory device according to an embodiment of the present invention may be applied to dynamic random access memories (DRAMs), or synchronous dynamic random access memories (DRAMs), but it is not limited thereto. It may be applied to static random access memories (SRAMs), flash memories, ferroelectric random access memories (FeRAMs), magnetic random access memories (MRAMs), or phase change random access memories (PRAMs).

The above-described memory device according to an embodiment of the present invention can be used, for example, in desktop computers, portable computers, computing memories used in servers, graphics memories having various specs, and mobile electronic devices as technology continues to evolve. Further, the above-described semiconductor device may be provided to various digital applications such as mobile recording mediums including a memory stick, multimedia card (MMC), secure digital (SD), compact flash (CF), extreme digital (xD) picture card, and a universal serial bus (USB) flash device as well as various applications such as MP3P, portable multimedia player (PMP), a digital camera, a camcorder, and a mobile phone. A semiconductor device may be applied to a technology such as multi-chip package (MCP), disk on chip (DOC), or embedded device. The semiconductor device may be applied to a CMOS image sensor to be provided to various fields such as a camera phone, a web camera, and a small-size image capture device for medicine.

As described above, the semiconductor memory device and the method for manufacturing the same according to an embodiment of the present invention provides the following effects.

First, dummy patterns of the mat edge (such as buried dummy gates) can be formed securely and reliably with a space margin, without experiencing gap-fill fail.

Second, as gap fill defects decrease in the dummy region, IDD defects due to electrical short between a word line driver contact and the substrate (for example 100) below the buried dummy gates (for example 115c, 115d), is prevented.

Third, contact resistance related to the buried dummy gates (for example 115c, 115d) can be maintained relatively low.

Fourth, the definite pattern separation can prevent a bridge phenomenon of the buried gate.

As a result of one or more of these features, device performance and reliability are improved.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

1. A semiconductor device, comprising:
a first active region in a cell region of a substrate,
a second active region in a dummy region of the substrate, the dummy region extending from the cell region,
first and second buried cell gates arranged to pass across the first active region, wherein the first and the second buried cell gates are parallel to each other,
first and second buried dummy gates arranged to pass across the second active region, wherein first and second buried dummy gates are parallel to each other and extend from the first and the second buried cell gates, respectively, and
an insulating film formed between first and second buried dummy gates in the second active region.

2. The semiconductor device according to claim 1, wherein the insulating film is configured to insulate the first and the second buried dummy gates from the substrate.

3. The semiconductor device according to claim 1, wherein the buried gate includes tungsten.

4. The semiconductor device of claim 1, wherein the insulating film extends from the substrate.

5. The semiconductor device of claim 1,
wherein widths of the first and the second buried cell gates are substantially same.

6. The semiconductor device of claim 5,
wherein widths of the first and the second buried dummy gates are substantially same as widths of the first and the second buried cell gates, respectively.

7-8. (canceled)

9. A method for manufacturing a semiconductor device,
providing a first active region in a cell region of a substrate;
providing a second active region in a dummy region of the substrate, the dummy region extending from the cell region;
patterning the substrate in the cell region to form a first trench passing across the first active region, the first trench having a width W1;
patterning the substrate in the cell region to form a second trench spaced apart from the first trench by a width W2, wherein the second trench is substantially parallel to the first trench and passes across the first active region, wherein the second trench has a width W3,
patterning the substrate in the dummy region to form a third trench, wherein the third trench has a width (W1+W2+W3) and extends from the first and the second trenches to pass across the second active region,
filling the first and second trenches with first conductive material to form first and second buried cell gates,
filling the third trench with the second conductive material to form a dummy conductive pattern,
forming a fourth trench in the middle of the conductive pattern to divide the dummy conductive pattern into first and second buried dummy gates, and
filling the fourth trench with insulating material to form an insulating film.

10. The method of claim 9,
wherein the first buried dummy gate is coupled to the first buried cell gate,
wherein the second buried dummy gate is coupled to the second buried cell gate, and
wherein the insulating film is configured to extend from the substrate between the first and the second buried cell gates.

11. The method of claim 10,
wherein the first trench is connected to the third trench,
wherein the second trench is connected to the third trench,
wherein the first conductive material and the second conductive material are same, and
wherein the step of filling the first and second trenches with the first conductive material and the step of filling the third trench with the second conductive material are performed substantially at the same time.

12. The method of claim 10,
wherein a width of the insulating film is substantially the same as W2.

13. The method of claim 10,
wherein a width of the first buried dummy gate is substantially as same as W1, and
wherein a width of the second buried dummy gate is substantially as same as W3.

14. (canceled)

15. A memory cell comprising:
a transistor including a buried gate formed at both sidewalls of a trench disposed in a semiconductor substrate, an insulating film obtained by burying a space between the buried gates to penetrate the middle portion of the trench and a gate junction region; and
a storage unit connected to the gate junction region.

16. The memory cell according to claim 15, wherein the buried gate is formed in a dummy region of an edge of a cell region.

17. The memory cell according to claim 15, wherein the storage unit is a capacitor.

18-25. (canceled)
